(19) United States
(12) Patent Application Publication
(10) Pub. No.: US 2024/0413041 A1
(43) Pub. Date: Dec. 12, 2024

(54) WIRING SUBSTRATE, ELECTRONIC DEVICE, AND METHOD OF MANUFACTURING THE WIRING SUBSTRATE

(71) Applicant: SHINKO ELECTRIC INDUSTRIES CO., LTD., Nagano-shi (JP)

(72) Inventor: Kenichi Mori, Nagano (JP)

(21) Appl. No.: 18/735,353

(22) Filed: Jun. 6, 2024

(30) Foreign Application Priority Data
Jun. 12, 2023 (JP) 2023-096421

(51) Int. Cl. H01L 23/367; H01L 23/498; H01L 25/10

(52) U.S. Cl. CPC H01L 23/367; H01L 23/49838; H01L 25/105; H01L 2225/1058

(57) ABSTRACT

A wiring substrate includes a metallic plate, a first through-hole, an insulating layer, a second through-hole, a wiring layer, and feedthrough wiring. The first through-hole is formed in the metallic plate. The insulating layer covers both surfaces of the metallic plate and an inner wall surface of the first through-hole. The second through-hole is formed on an inner side of the insulating layer in the first through-hole. The wiring layer is laminated on the insulating layer on both surface sides of the metallic plate. The feedthrough wiring is formed in the second through-hole, and connects the wiring layer disposed on both surface sides of the metallic plate. The metallic plate includes a bent portion that is bent in a bottomed box shape and that forms a space on one of the surface sides of the metallic plate.

### CROSS-REFERENCE TO RELATED APPLICATION

This application is based upon and claims the benefit of priority of the prior Japanese Patent Application No. 2023-096421, filed on Jun. 12, 2023, the entire contents of which are incorporated herein by reference.

### FIELD

The embodiments discussed herein are related to, a wiring substrate, an electronic device, and a method of manufacturing the wiring substrate.

### BACKGROUND

In recent years, in order to implement a high-density component mounting technique, for example, a wiring substrate with built-in electronic component in which, for example, an electronic component, such as a semiconductor chip, is built in an interior portion of the board has been drawing attention. This type of wiring substrate is manufactured by providing a cavity on a substrate that is formed by laminating layers formed by, for example, insulating layers having insulation properties and conductive wiring layers, and filling an insulation-property resin that covers the electronic component in a cavity in which the electronic component is arranged.
Patent Document 1: Japanese Laid-open Patent Publication No. 2016-96292

However, in the wiring substrate having the electronic component built in, there is a problem in that it is difficult to sufficiently radiate heat generated by the electronic component. In other words, a portion around the built in electronic components is covered by an insulation-property resin having low thermal conductivity, so that the head generated by the electronic component is radiated from a metal terminal having high thermal conductivity to the outside by passing through the wiring layers provided on the substrate. However, the area occupied by the terminal is small in a surface area of the electronic component, and the efficiency of radiation is not so high. As a result of this, in particular, in the case of a relatively large amount of heat generation of electronic component, it is difficult to sufficiently radiate heat from the terminals of the electronic component.

### SUMMARY

According to an aspect of an embodiment, a wiring substrate includes a metallic plate; a first through-hole that is formed in the metallic plate; an insulating layer that covers both surfaces of the metallic plate and an inner wall surface of the first through-hole; a second through-hole that is formed on an inner side of the insulating layer in the first through-hole; a wiring layer that is laminated on the insulating layer on both surface sides of the metallic plate; and feedthrough wiring that is formed in the second through-hole, and that connects the wiring layer disposed on both surface sides of the metallic plate, wherein the metallic plate incudes a bent portion that is bent in a bottomed box shape and that forms a space on one of the surface sides of the metallic plate.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a diagram illustrating a configuration of a wiring substrate according to a first embodiment;

FIG. 2 is a diagram illustrating a configuration of the wiring layer on an upper surface side of a metallic plate;

FIG. 3 is a flowchart illustrating a method of manufacturing the wiring substrate according to the first embodiment;

FIG. 4 is a diagram illustrating a structure of the metallic plate;

FIG. 5 is a diagram illustrating a specific example of a through-hole forming step;

FIG. 6 is a diagram illustrating a specific example of an insulating layer forming step;

FIG. 7 is a diagram illustrating a specific example of a through-hole forming step;

FIG. 8 is a diagram illustrating a specific example of a DFR patterning step;

FIG. 9 is a diagram illustrating a specific example of an electrolytic copper plating step;

FIG. 10 is a diagram illustrating a specific example of a DFR stripping step;

FIG. 11 is a diagram illustrating a specific example of a solder resist layer forming step;

FIG. 12 is a flowchart illustrating a method of manufacturing an electronic device according to the first embodiment;

FIG. 13 is a diagram illustrating a structure of a mounting substrate;

FIG. 14 is a diagram illustrating a specific example of an IC chip fixing step;

FIG. 15 is a diagram illustrating a specific example of a wiring substrate mounting step;

FIG. 16 is a diagram illustrating a configuration of an electronic device;

FIG. 17 is a diagram illustrating a configuration of a component mounting substrate;

FIG. 18 is a diagram illustrating a configuration of a wiring substrate according to a second embodiment;

FIG. 19 is a flowchart illustrating a method of manufacturing a wiring substrate according to the second embodiment;

FIG. 20 is a diagram illustrating a specific example of a solder resist layer forming step;

FIG. 21 is a diagram illustrating a specific example of a buildup step;

FIG. 22 is a diagram illustrating a specific example of a solder resist layer forming step; and

FIG. 23 is a top view illustrating a configuration of a wiring substrate according to a third embodiment.

### DESCRIPTION OF EMBODIMENTS

Preferred embodiments of a wiring substrate, an electronic device, and a method of manufacturing a wiring substrate disclosed in the present invention will be described in detail below with reference to the accompanying drawings. Furthermore, the disclosed technology is not limited by the embodiments.

### First Embodiment

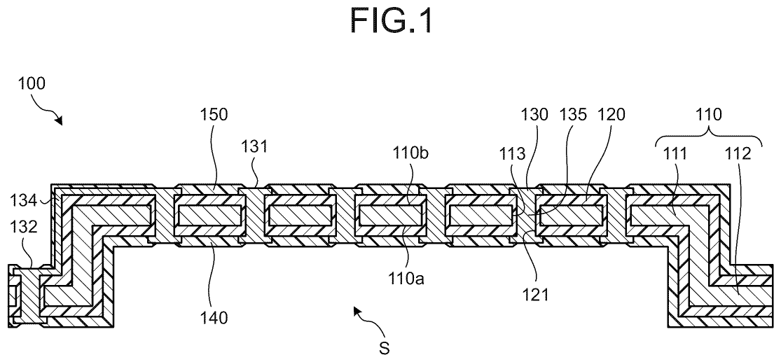

FIG. 1 is a diagram illustrating a configuration of a wiring substrate 100 according to a first embodiment. In FIG. 1, a cross-sectional view of the wiring substrate 100 is schematically illustrated. The wiring substrate 100 illustrated in FIG. 1 may be used as a relay substrate that electrically connects an electronic component and another electronic component in, for example, an electronic device on which an electronic component, such as a semiconductor chip, is mounted.

The wiring substrate 100 includes a metallic plate 110, an insulating layer 120, a wiring layer 130, and solder resist layers 140 and 150. Furthermore, in the following, a description will be given on the assumption that one of the surfaces of the metallic plate 110 on which the solder resist layer 140 is formed is a lower surface 110a, whereas the other of the surfaces of the metallic plate 110 on which the solder resist layer 150 is formed is an upper surface 110b. However, the wiring substrate 100 may be used by, for example, vertically inverting the surfaces, or may be used in an arbitrary orientation.

The metallic plate 110 is a metallic plate-shaped member, and is a base material of the wiring substrate 100. A material of the metallic plate 110 used may be, for example, a plate-shaped member or the like made of copper, aluminum, or the like. The surface of the metallic plate 110 may be covered by, for example, a protection film, such as an antioxidant film. The thickness of the metallic plate 110 may be set to about, for example, 150 to 300 μm.

In the metallic plate 110, a through-hole 113 (one example of a first through-hole) passing through the metallic plate 110 in the thickness direction is formed. The through-hole 113 is a through-hole formed in a cylindrical shape having an opening portion with a diameter of about, for example, 90 to 170 μm.

The insulating layer 120 is a layer that covers both the lower surface 110a and the upper surface 110b of the metallic plate 110 and an inner wall surface of the through-hole 113. The insulating layer 120 is formed by using, for example, an insulation resin, such as an epoxy resin or a polyimide resin. On an inner side of the insulating layer 120 in the through-hole 113, a through-hole 121 (one example of a second through-hole) is formed, and feedthrough wiring 135 is formed in an interior portion of the through-hole 121.

The wiring layer 130 is laminated on the insulating layer 120 on both surface (the lower surface 110a and the upper surface 110b) sides of the metallic plate 110. The wiring layer 130 is made of, for example, metal, such as copper or a copper alloy. The wiring layer 130 disposed on both surface (the lower surface 110a and the upper surface 110b) sides of the metallic plate 110 is connected by the feedthrough wiring 135 as needed.

The solder resist layer 140 is a layer that covers the wiring layer 130 that is disposed on the lower surface 110a side of the metallic plate 110, and that covers the wiring. The solder resist layer 140 is a layer constituted of, for example, a photosensitive resin, such as an acrylic resin and a polyimide resin, having an insulation property, and is one of insulating layers. Furthermore, the solder resist layer 140 may be formed by using, for example a non-photosensitive resin having an insulation property, such as an epoxy resin.

The solder resist layer 140 side of the wiring substrate 100 is a surface that is connected to the electronic component and the mounting substrate. An opening portion is formed in the solder resist layer 140 at the position that is electrically connected to the electronic component and the mounting substrate, and the wiring layer 130 is exposed from this opening portion.

The solder resist layer 150 is a layer that covers the wiring layer 130 disposed on the upper surface 110b side of the metallic plate 110, and that protects the wiring. The solder resist layer 150 is a layer constituted of, for example, a photosensitive resin, such as an acrylic resin and a polyimide resin, having an insulation property, and is one of the insulating layers. Furthermore, the solder resist layer 150 may be formed by using, for example, a non-photosensitive resin, such as an epoxy resin, having an insulation property.

The solder resist layer 150 side of the wiring substrate 100 is a surface on which another electronic component that is different from the electronic component that is connected to the solder resist layer 140 side is mounted. At the position on which the other electronic component is mounted, an opening portion is formed in the solder resist layer 150, and the wiring layer 130 is exposed from the opening portion. Furthermore, at the position that is different from the position on which the other electronic component is mounted, an opening portion is also formed in the solder resist layer 150, and the wiring layer 130 is exposed from the opening portion.

In the following, the metallic plate 110 will be described in detail. The metallic plate 110 includes a bent portion 111 and a flange portion 112.

The bent portion 111 is formed such that a plate-shaped member made of metal is bent in a bottomed box shape. The bent portion 111 forms a space S that is able to accommodate an electronic components on the lower surface 110a side of the metallic plate 110. In other words, the space S is formed in an area surrounded by the bottom and the side walls of the bent portion 111.

In the present embodiment, by forming the bent portion 111 at the metallic plate 110, the bottom and the side walls of the bent portion 111 are disposed opposite the upper surface and the side surfaces of the electronic component in a relatively large area by way of the solder resist layer 140 and the insulating layer 120. As a result of this, heat generated in the electronic component that is accommodated in the space S is efficiently conducted to the metallic plate 110 by way of the solder resist layer 140 and the insulating layer 120, and is radiated from the metallic plate 110. Consequently, it is possible to improve heat radiation efficiency of the wiring substrate 100.

The flange portion 112 is formed such that the lower end portion of an outer periphery of the side walls of the bent portion 111 protrudes in a direction away from the space S. The flange portion 112 forms a surface connected to the mounting substrate on the lower surface 110a side of the metallic plate 110. In other words, the lower surface of the solder resist layer 140 corresponding to the flange portion 112 is connected to the mounting substrate.

In the present embodiment, as a result of forming the flange portion 112 on the metallic plate 110, a radiation area of the metallic plate 110 is increased by an amount corresponding to the flange portion 112, and it is possible to form a connecting surface that is connected to the mounting substrate on the lower surface of the solder resist layer 140. As a result of this, the heat conducted from the electronic component accommodated in the space S to the metallic plate 110 is efficiently radiated to the mounting substrate from the metallic plate 110 by way of the insulating layer 120 and the solder resist layer 140. Consequently, it is possible to further improve the heat radiation efficiency of the wiring substrate 100.

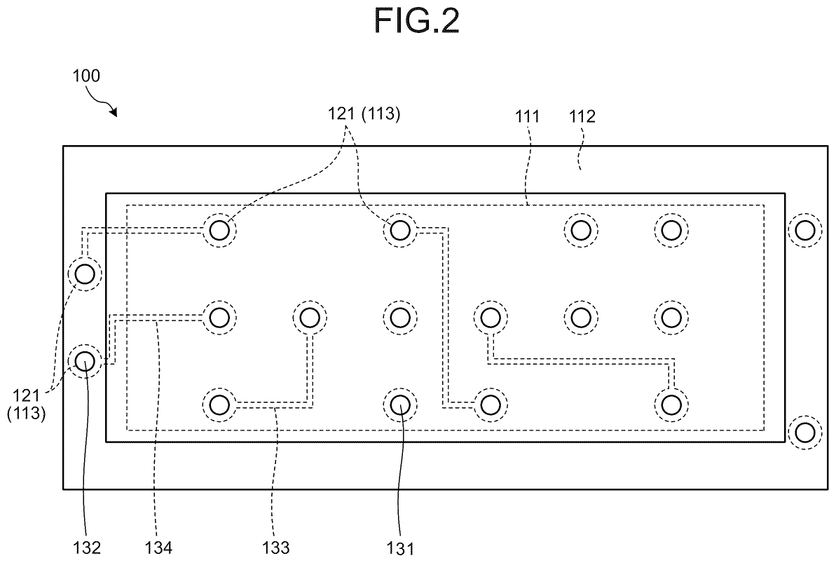

FIG. 2 is a diagram illustrating a configuration of the wiring layer 130 disposed on the upper surface 110b side of the metallic plate 110. As illustrated in FIG. 1 and FIG. 2, the through-holes 113 are formed at the bent portion 111 and the flange portion 112 provided on the metallic plate 110. Pads 131 (one example of a first pad) that is electrically connected to another electronic component is formed on the wiring layer 130 that is disposed on the upper surface 110b side of the metallic plate 110 at a position corresponding to the position of the through-hole 113 provided at the bent portion 111. Furthermore, a pad 132 (one example of a second pad) that is used for feeding of electricity and signal transmission from the mounting substrate to the other electronic component is formed on the wiring layer 130 that is disposed on the upper surface 110b side of the metallic plate 110 at a position corresponding to the position of the through-hole 113 provided at the flange portion 112.

Both of the pads 131 are connected by wiring 133. As a result of this, signal transmission is able to be implemented in a region in which the bent portion 111 and the pad 131 are overlapped each other when viewed from the top.

In contrast, the pad 131 and the pad 132 are connected by wiring 134. As a result of this, in a region in which the bent portion 111 and the flange portion 112 are overlapped each other when viewed from the top, it is possible to implement the feeding of electricity and the signal transmission from the mounting substrate to the other electronic component.

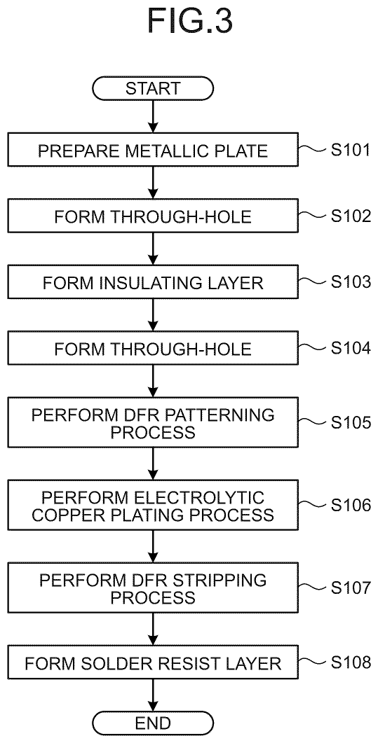

In the following, a method of manufacturing the wiring substrate 100 configured as described above will be specifically described by using examples with reference to FIG. 3. FIG. 3 is a flowchart illustrating the method of manufacturing the wiring substrate 100 according to the first embodiment.

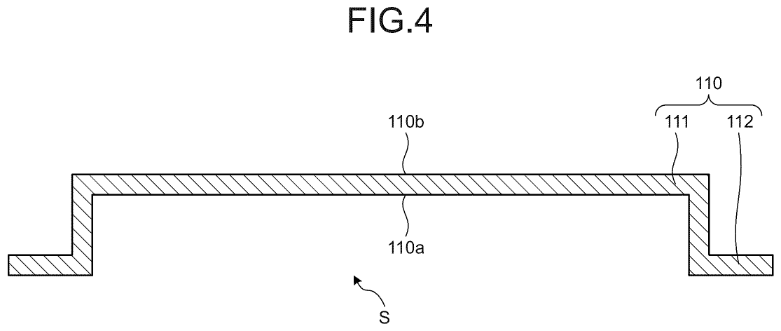

First, the metallic plate 110 serving as a base material of the wiring substrate 100 is prepared (Step S101). In other words, by performing, for example, press working on the plate-shaped member made of metal, for example, as illustrated in FIG. 4, the metallic plate 110 having the bent portion 111 and the flange portion 112 is formed. FIG. 4 is a diagram illustrating the structure of the metallic plate 110. The bent portion 111 forms the space S that is able to accommodate the electronic component on the lower surface 110a side of the metallic plate 110 by being bent in a bottomed box shape. At the lower end portion of the outer periphery of the side walls of the bent portion 111, the flange portion 112 is formed so as to protrude in the direction away from the space S.

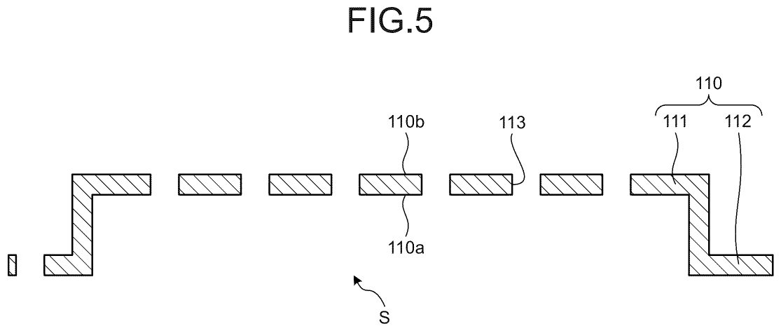

Then, the through-hole 113 that passes through the metallic plate 110 in the thickness direction is formed (Step S102). The through-hole 113 is formed, as illustrated in, for example, FIG. 5, on both of the bent portion 111 and the flange portion 112 provided on the metallic plate 110, and has a cylindrical shape having an opening portion with a diameter of about, for example, 90 to 170 μm. FIG. 5 is a diagram illustrating a specific example of a through-hole forming step. The through-hole 113 is formed by, for example, a punching process or an etching process.

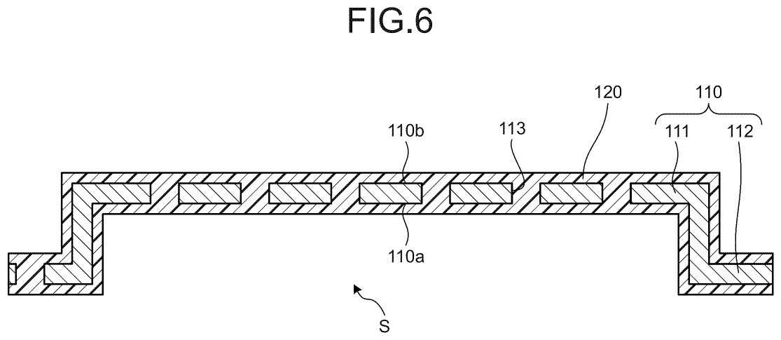

After the through-hole 113 has been formed in the metallic plate 110, an insulating layer is formed on the lower surface 110a and the upper surface 110b of the metallic plate 110 (Step S103). In other words, on the lower surface 110a and the upper surface 110b of the metallic plate 110, the insulating layer 120 formed by using, for example, a non-photosensitive and thermosetting resin, such as an epoxy resin or a polyimide resin, having thermal resistance is laminated. A part of the insulating layer 120 laminated on the lower surface 110a and the upper surface 110b of the metallic plate 110 fills, as illustrated in, for example, FIG. 6, the through-hole 113. FIG. 6 is a diagram illustrating a specific example pf an insulating layer forming step. The insulating layer 120 disposed on the lower surface 110a side and the upper surface 110b side of the metallic plate 110 is integrated with the through-hole 113, and covers both the lower surface 110a and the upper surface 110b of the metallic plate 110, so that a piece of the insulating layer 120 is formed such that a part of the insulating layer 120 fills the through-hole 113.

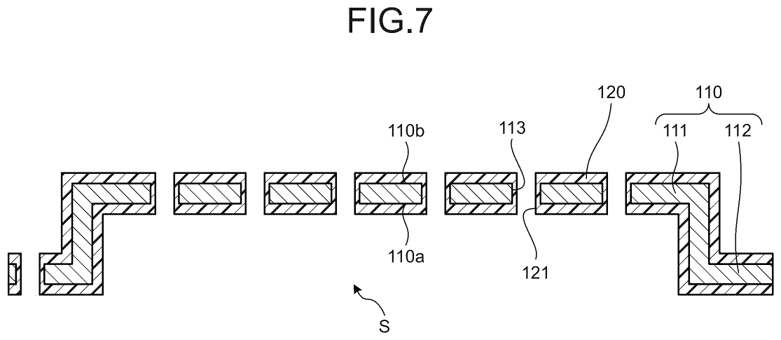

Then, the through-hole 121 passing through the insulating layer 120 is formed at a portion in which the insulating layer 120 fills the through-hole 113 (Step S104). The through-hole 121 is formed such that, as illustrated in, for example, FIG. 7, the insulating layer 120 in the through-hole 113 remains. FIG. 7 is a diagram illustrating a specific example of a through-hole forming step. The through-hole 121 is formed by performing, for example, laser beam machining or drilling.

When the through-hole 121 has been formed in the insulating layer 120, the wiring layer 130 is formed on the insulating layer 120 on the both surface (the lower surface 110a and the upper surface 110b) sides of the metallic plate 110. Specifically, first, a seed layer is formed by performing, for example, electroless copper plating on the surface of the insulating layer 120 including the inner wall surface of the through-hole 121, and then, a dry film resist (DFR) is pasted on a seed layer. Then, an opening portion is formed by performing patterning of the DER at a position in which a wiring pattern of the wiring layer 130 has been formed (Step S105).

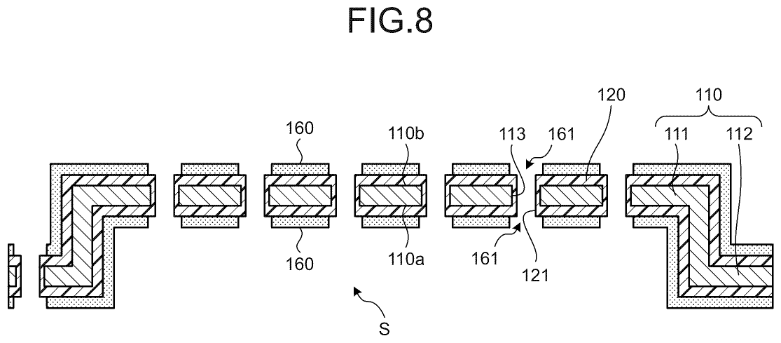

In other words, as illustrated in for example, FIG. 8, a DFR 160 is pasted on the seed layer (not illustrated) disposed on the surface of the insulating layer 120 on the both surface (the lower surface 110a and the upper surface 110b) sides of the metallic plate 110, and an opening portion 161 is formed at a position in which the wiring pattern of the wiring layer 130 is formed. FIG. 8 is a diagram illustrating a specific example of a DFR patterning step.

When the patterning of the DFR 160 has been performed, by performing electrolytic copper plating (Step S106), copper is deposited to the opening portion 161, and the wiring layer 130 having a desired wiring pattern is formed. For example, on the wiring layer 130 disposed on the upper surface 110b side of the metallic plate 110, the wiring pattern including the pads 131 and 132 and the wiring 133 is formed.

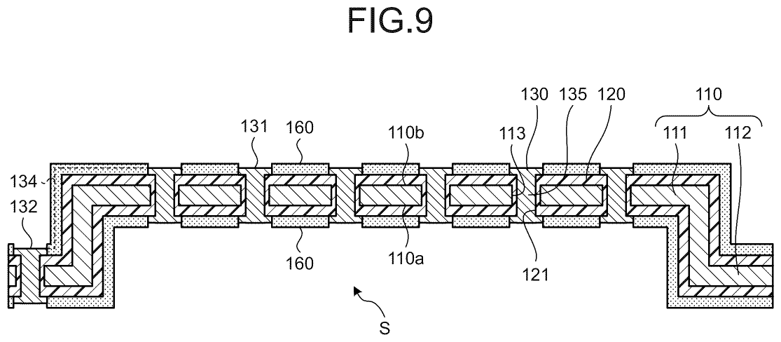

At this time, as illustrated in, for example, FIG. 9, the feedthrough wiring 135 is formed in the through-hole 121 provided in the insulating layer 120 as a result of the electrolytic copper plating being filled, and the wiring layer 130 disposed on the both surface (the lower surface 110a and the upper surface 110b) sides of the metallic plate 110 is electrically connected. FIG. 9 is a diagram illustrating a specific example of an electrolytic copper plating step.

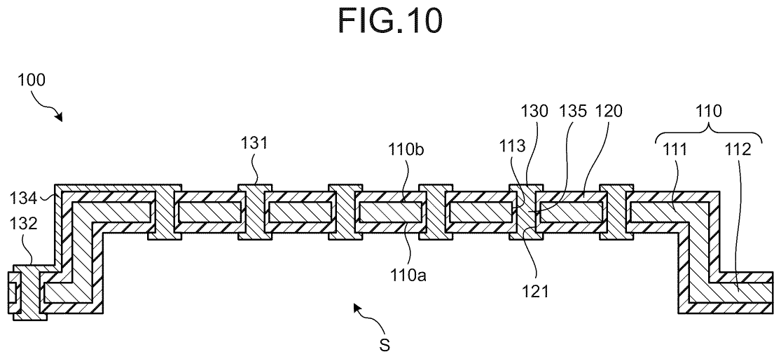

When the wiring layer 130 has been formed, as illustrated in, for example, FIG. 10, the DFR 160 is stripped (Step S107), and then, the seed layer other than the portion in which the wiring pattern is formed is removed by performing flash etching. FIG. 10 is a diagram illustrating a specific example of a DFR stripping step. For example, sodium hydroxide or an amine-based alkaline stripping solution is used to strip the DFR 160. In this way, the wiring layer 130 is formed on the insulating layer 120 on the both surface (the lower surface 110a and the upper surface 110b) sides of the metallic plate 110.

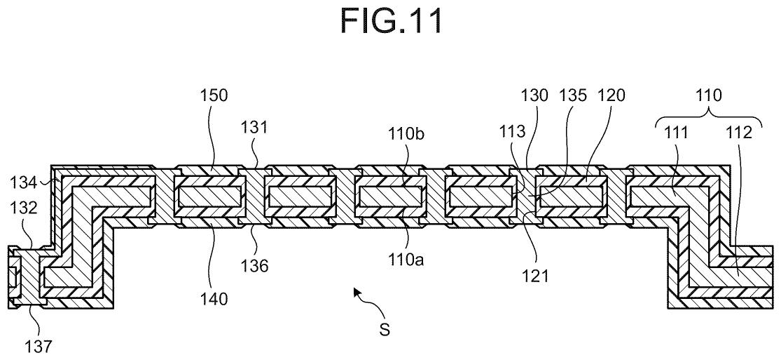

After the wiring layer 130 has been formed on the insulating layer 120 on the both surface (the lower surface 110a and the upper surface 110b) sides of the metallic plate 110, the wiring layer 130 is covered by the solder resist layers 140 and 150 (Step S108). In other words, as illustrated in, for example, FIG. 1, the wiring layer 130 disposed on the lower surface 110a side of the metallic plate 110 is covered by the solder resist layer 140. An opening portion is formed on the solder resist layer 140, pads 136 and 137 that are formed on the wiring layer 130 disposed on the lower surface 110a side of the metallic plate 110 is exposed from this opening portion. The pad 136 is able to be electrically connected to the electronic component that is accommodated in the space S, whereas the pad 137 is able to be electrically connected to the mounting substrate on which the wiring substrate 100 is mounted. On the other hand, the wiring layer 130 disposed on the upper surface 110b side of the metallic plate 110 is covered by the solder resist layer 150. An opening portion is formed in the solder resist layer 150, the pads 131 and 132 that are formed in the wiring layer 130 disposed on the upper surface 110b side of the metallic plate 110 is exposed from this opening portion. The pad 131 is able to be electrically connected to the other electronic component that is different from the electronic component that is accommodated in the space S. FIG. 11 is a diagram illustrating a specific example of a solder resist layer forming step. As a result of the solder resist layers 140 and 150 being formed, the wiring substrate 100 has been completed.

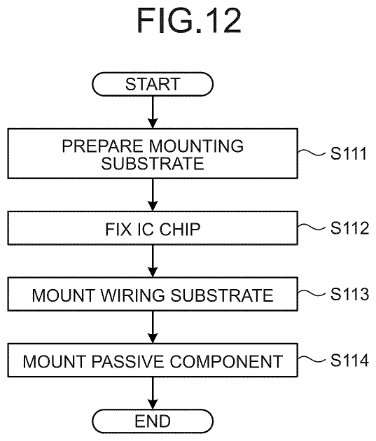

In an electronic device on which, for example, the electronic component, such as a semiconductor chip, is mounted, the wiring substrate 100 is able to be used as a relay substrate that electrically connects an electronic component and the other electronic component. In the following, a method of manufacturing an electronic device that includes the wiring substrate 100 as a relay substrate will be specifically described by using examples with reference to FIG. 12. FIG. 12 is a flowchart illustrating the method of manufacturing the electronic device according to the first embodiment.

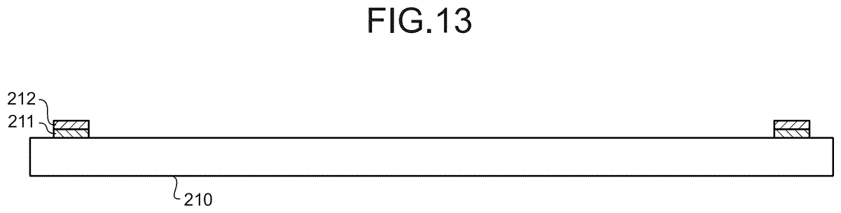

First, a mounting substrate 210 (one example of a first wiring substrate) serving as a base material of the electronic device is prepared (Step S111). A pad 211 is formed on the upper surface of the mounting substrate 210, as illustrated in, for example, FIG. 13. FIG. 13 is a diagram illustrating the structure of the mounting substrate 210. The pad 211 is formed of, for example, a conductive material, such as copper, and serves as a connecting terminal when the mounting substrate 210 is bonded to the wiring substrate 100 (one example of a second wiring substrate). Furthermore, solder 212 that is used to bond the mounting substrate 210 to the wiring substrate 100 is applied on the pad 211. In order to apply the solder 212, for example, soldering paste is printed.

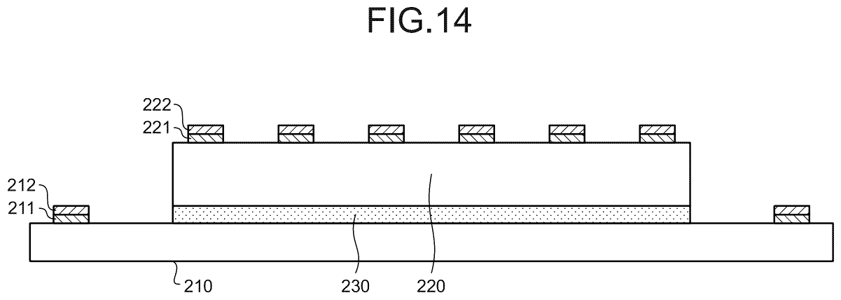

Subsequently, an IC chip 220 (one example of an electronic component) is fixed on the upper surface of the mounting substrate 210 (Step S112). In other words, as illustrated in, for example, FIG. 14, the IC chip 220 is fixed on the upper surface of the mounting substrate 210 by way of an adhesive layer 230. FIG. 14 is a diagram illustrating a specific example of an IC chip fixing step. Furthermore, solder 222 that is used to bond the IC chip 220 and the wiring substrate 100 is applied to an electrode 221 of the IC chip 220. In order to apply the solder 222, for example, soldering paste is printed.

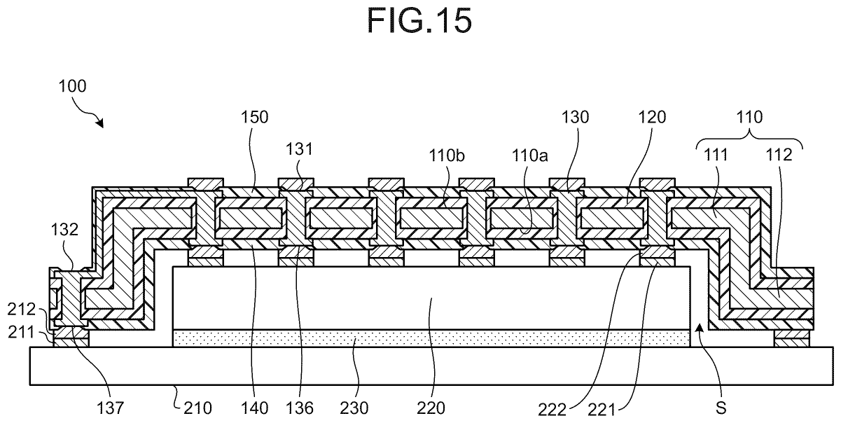

When the IC chip 220 has been fixed to the upper surface of the mounting substrate 210, the wiring substrate 100 is mounted on the IC chip 220 and the mounting substrate 210 (Step S113). In other words, as illustrated in, for example, FIG. 15, the IC chip 220 disposed on the mounting substrate 210 is accommodated in the space S provided in the wiring substrate 100, and the pad 136 provided on the wiring substrate 100 is connected to the electrode 221 of the IC chip 220 by way of the solder 222. Furthermore, the pad 137 provided on the wiring substrate 100 is connected to the pad 211 provided on the mounting substrate 210 by way of the solder 212. The connection made by using the solders 212 and 222 is performed by, for example, a reflow process. FIG. 15 is a diagram illustrating a specific example of a wiring substrate mounting step.

The upper surface and the side surfaces of the IC chip 220 is disposed opposite the bottom and the side walls of the bent portion 111 provided on the metallic plate 110 while the IC chip 220 is accommodated in the space S. As a result of this, heat generated in the IC chip 220 that is accommodated in the space S is efficiently conducted to the metallic plate 110 by way of the solder resist layer 140 and the insulating layer 120, and is radiated from the metallic plate 110. Consequently, it is possible to improve the heat radiation efficiency of the wiring substrate 100.

Furthermore, the flange portion 112 provided on the metallic plate 110 is able to form a connecting surface that is brought into contact with the mounting substrate 210 on the lower surface of the solder resist layer 140. As a result of this, the heat conducted from the IC chip 220 accommodated in the space S to the metallic plate 110 is efficiently radiated from the metallic plate 110 to the mounting substrate 210 by way of both the insulating layer 120 and the solder resist layer 140. Consequently, it is possible to further improve the heat radiation efficiency of the wiring substrate 100 as compared to a case in which the flange portion 112 is not formed on the metallic plate 110.

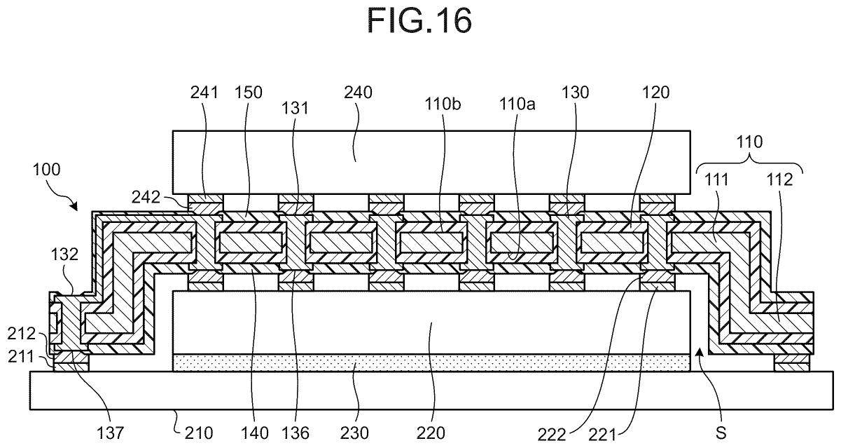

When the wiring substrate 100 is mounted on the IC chip 220 and the mounting substrate 210, for example, a passive component, such as an inductor, is mounted on the wiring substrate 100 (Step S114). In other words, as illustrated in, for example FIG. 16, a passive component 240 (one example of the other electronic component) is mounted on the upper surface of the wiring substrate 100. For example, an electrode 241 of the passive component 240 is connected to the pad 131 provided on the wiring substrate 100 by way of solder 242. As a result of this, an electronic device on which the IC chip 220 and the passive component 240 are mounted and both the IC chip 220 and the passive component 240 are electrically connected by the wiring substrate 100 is obtained. FIG. 16 is a diagram illustrating a configuration of the electronic device. For example, an active component, such as an IC chip, may be mounted on the pad 131 instead of the passive component 240. Furthermore, for example, an active component, such as an IC chip, may be mounted on the pad 131 together with the passive component 240. Furthermore, examples of the passive component 240 include, in addition to the inductor, a capacitor and a resistance.

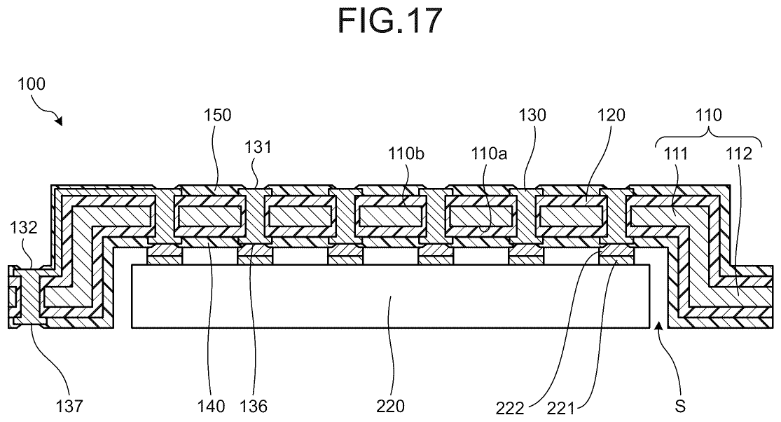

Moreover, in the first embodiment described above, a case has been described as an example in which the wiring substrate 100 is used as the relay substrate in the electronic device, but it may be possible to form a component mounting substrate on which the electronic component is mounted from the wiring substrate 100. Specifically, as illustrated in FIG. 17, as a result of the IC chip 220 being mounted on the lower surface of the wiring substrate 100, it is possible to obtain a component mounting substrate on which the IC chip 220 is mounted. FIG. 17 is a diagram illustrating a configuration of a component mounting substrate. For example, the IC chip 220 is accommodated in the space S provided in the wiring substrate 100, the pad 136 disposed on the wiring substrate 100 is connected to the electrode 221 of the IC chip 220 by way of the solder 222. In other words, the component mounting substrate illustrated in FIG. 17 indicates the component mounting substrate from which the mounting substrate 210 and the passive component 240 are excluded from the electronic device that is illustrated in FIG. 16.

### Second Embodiment

In the first embodiment described above, the structure is assumed to be constituted such that the wiring layer 130 disposed on the upper surface 110b side of the metallic plate 110 is covered by the solder resist layer 150, but the insulating layer and the wiring layer may be laminated on the wiring layer 130 that is disposed on the upper surface 110b side of the metallic plate 110. Accordingly, in a second embodiment, the wiring substrate 100 in which the insulating layer and the wiring layer are laminated on the wiring layer 130 that is disposed on the upper surface 110b side of the metallic plate 110 will be described.

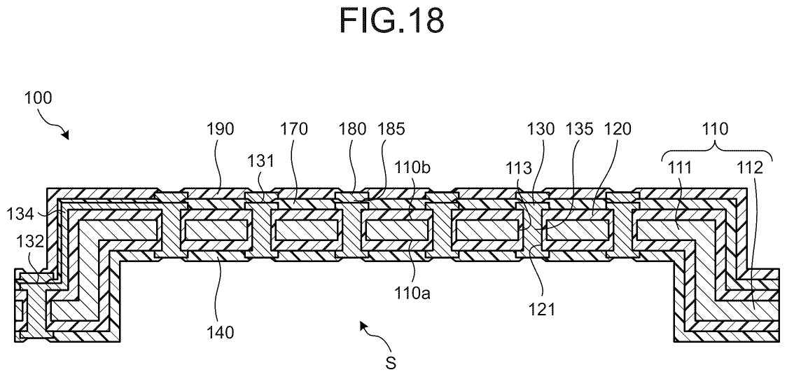

FIG. 18 is a diagram illustrating a configuration of the wiring substrate 100 according to the second embodiment. In FIG. 18, a cross-sectional view of the wiring substrate 100 is schematically illustrated. In FIG. 18, components that are the same as those illustrated in FIG. 1 are assigned the same reference numerals.

The wiring substrate 100 illustrated in FIG. 18 includes, instead of the solder resist layer 150 illustrated in FIG. 1, an insulating layer 170 (one example of another insulating layer), a wiring layer 180 (one example of another wiring layer), and a solder resist layer 190.

The insulating layer 170 is a layer that covers the wiring layer 130 disposed on the upper surface 110b side of the metallic plate 110. The insulating layer 170 is formed by using, similarly to the insulating layer 120, for example, an insulation resin, such as an epoxy resin or a polyimide resin.

The wiring layer 180 is laminate on the insulating layer 170. The wiring layers 130 and 180 that are adjacent by way of the insulating layer 170 is connected as needed by a via wiring 185 that is provided in the insulating layer 170.

The solder resist layer 190 is a layer that covers the wiring layer 180 and that protects wiring. The solder resist layer 190 is a layer that is made of, for example, a photosensitive resin, such as an acrylic resin and a polyimide resin, having an insulation property, and is one of insulating layers. Furthermore, the solder resist layer 190 may be formed by using, for example, a non-photosensitive resin, such as an epoxy resin, having an insulation property.

The solder resist layer 190 side of the wiring substrate 100 is a surface on which another electronic component that is different from the electronic component that is connected to the solder resist layer 140 side is mounted. At a position on which the other electronic component is mounted, an opening portion is formed in the solder resist layer 190, and the wiring layer 180 is exposed from this opening portion. Furthermore, at a position that is different from the position on which the other electronic component is mounted, an opening portion is also formed in the solder resist layer 190, the wiring layer 180 is exposed from this opening portion.

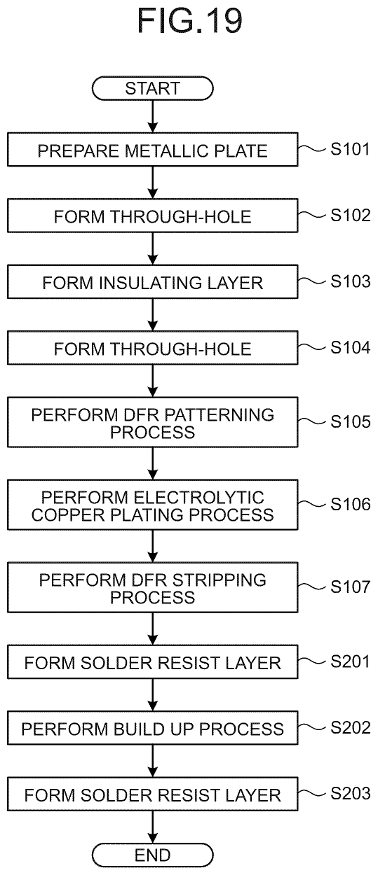

In the following, a method of manufacturing the wiring substrate 100 configured as described above will be specifically described by using examples with reference to FIG. 19. FIG. 19 is a flowchart illustrating the method of manufacturing the wiring substrate 100 according to the second embodiment. In FIG. 19, processes performed at steps that are the same as those illustrated in FIG. 3 are assigned the same steps.

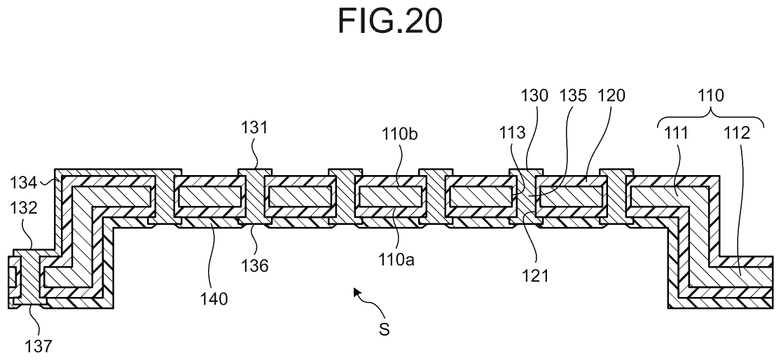

After the processes at Steps S105 to S107 have been performed and the wiring layer 130 has been formed on the insulating layer 120, as illustrated in, for example, FIG. 20, the wiring layer 130 disposed on the lower surface 110a side of the metallic plate 110 is covered by the solder resist layer 140 (Step S201). FIG. 20 is a diagram illustrating a specific example of a solder resist layer forming step. An opening portion is formed in the solder resist layer 140, the pads 136 and 137 that are formed in the wiring layer 130 disposed on the lower surface 110a side of the metallic plate 110 are exposed from this opening portion. The pad 136 is able to be electrically connected to the electronic component that is accommodated in the space S, whereas the pad 137 is able to be electrically connected to the mounting substrate on which the wiring substrate 100 is mounted.

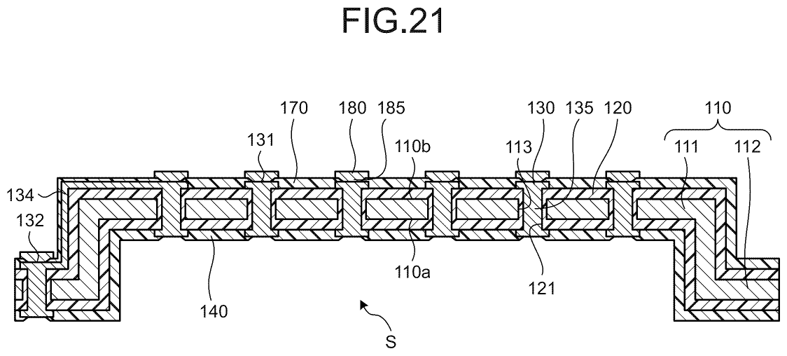

Subsequently, in the wiring layer 130 disposed on the upper surface 110b side of the metallic plate 110, the insulating layer 170 and the wiring layer 180 are sequentially built up (Step S202). Specifically, as illustrated in, for example, FIG. 21, the insulating layer 170 is laminated on the upper surface of the wiring layer 130, and the wiring layer 180 is formed on the upper surface of the insulating layer 170. FIG. 21 is a diagram illustrating a specific example of a buildup step. The insulating layer 170 if formed by using, for example, an insulation resin, such as an epoxy resin or a polyimide resin. The wiring layer 180 is formed by performing plating on a metal made of, for example, copper or the like. The wiring layer 180 and the wiring layer 130 are electrically connected as needed by the via wiring 185 that is provided in the insulating layer 170. The insulating layer 170 and the wiring layer 130 may be laminated in multiple times on the upper surface of the wiring layer 130.

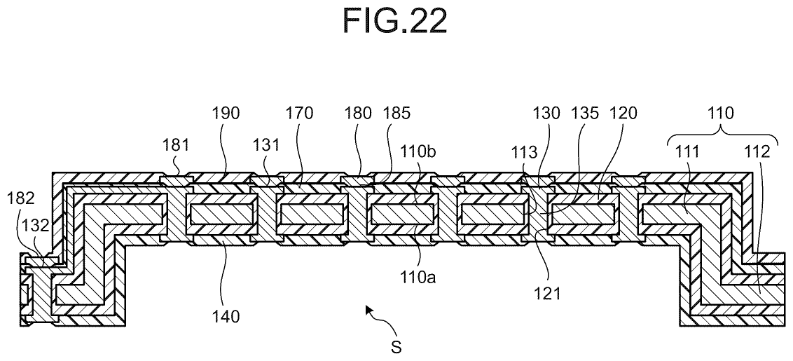

Then, the wiring layer 180 is covered by, as illustrated in, for example, FIG. 22, by the solder resist layer 190 (Step S203). FIG. 22 is a diagram illustrating a specific example of a solder resist layer forming step. An opening portion is formed in the solder resist layer 190, and pads 181 and 182 that are formed in the wiring layer 180 are exposed from this opening portion. The pad 181 is able to be electrically connected to another electronic component that is different from the electronic component that is accommodated in the space S. The wiring substrate 100 is completed as a result of the solder resist layer 190 being formed.

In the present embodiment, the insulating layer 170 and the wiring layer 180 are laminated on the wiring layer 130 disposed on the upper surface 110b side of the metallic plate 110, and both the wiring layer 180 and the wiring layer 130 are connected by the via wiring 185. As a result of this, it is possible to improve flexibility of a wiring layout of the wiring substrate 100.

### Third Embodiment

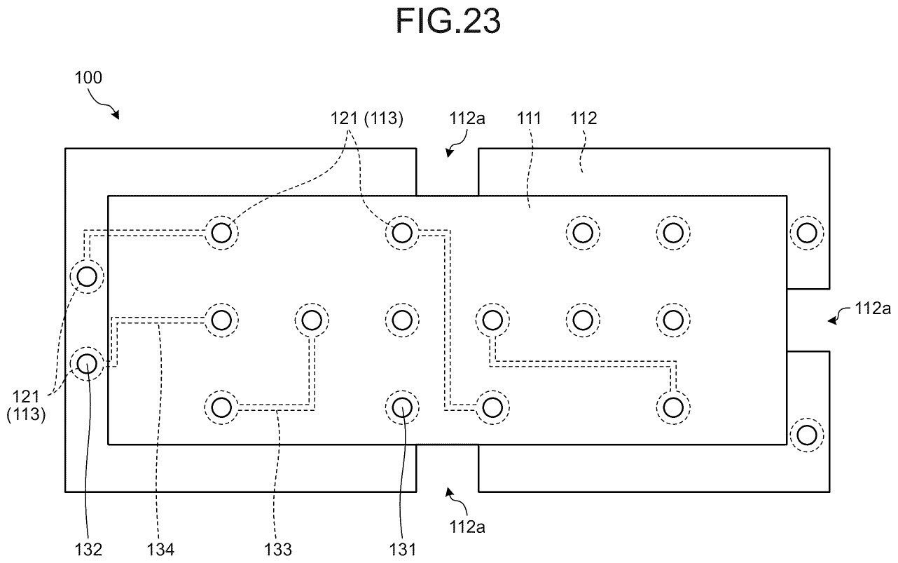

FIG. 23 is a top view illustrating a configuration of the wiring substrate 100 according to a third embodiment. In FIG. 23, components that are the same as those illustrated in FIG. 2 are assigned the same reference numerals. On the wiring substrate 100 illustrated in FIG. 23, the flange portion 112 provided on the metallic plate 110 is divided by way of slits 112a.

In the present embodiment, by providing the slits 112a in the flange portion 112, it is possible to take outside air into the space S that accommodates the electronic component from the slits 112a, and it is thus possible to improve cooling efficiency of the electronic component in the space S provided in the bent portion 111. Furthermore, it is possible to ensure the space for arranging the components on the mounting substrate at the positions of the slits 112a at the time of connection of the wiring substrate 100 with respect to the mounting substrate. As a result of this, it is possible to improve flexibility of a component layout of the mounting substrate side.

As described above, the wiring substrate (as one example, the wiring substrate 100) according to the embodiment includes the metallic plate (as one example, metallic plate 110), the first through-hole (as one example, the through-hole 113), the insulating layer (as one example, the insulating layer 120), the second through-hole (as one example, the through-hole 121), the wiring layer (as one example, the wiring layer 130), and the feedthrough wiring (as one example, the feedthrough wiring 135). The first through-hole is formed in the metallic plate. The insulating layer covers both surfaces (as one example, the lower surface 110a and the upper surface 110b) of the metallic plate and the inner wall surface of the first through-hole. The wiring layer is laminated on the insulating layer on both surface sides of the metallic plate. The feedthrough wiring is formed in the second through-hole and connects the wiring layer disposed on the both surface sides of the metallic plate. The metallic plate includes the bent portion (as one example, the bent portion 111) that is bent in a bottomed box shape and that forms the space (as one example, the space S) on one of the surface (as one example, the lower surface 110a) sides of the metallic plate. As a result of this, it is possible to improve the heat radiation efficiency of the wiring substrate.

Furthermore, the metallic plate may include the flange portion (as one example, the flange portion 112) that is formed at the outer periphery of the bent portion and that protrudes in the direction away from the space. As a result of this, it is possible to further improve the heat radiation efficiency of the wiring substrate.

Furthermore, the first through-hole may be formed in the bent portion and the flange portion. The wiring layer disposed on the other of the surface (as one example, the upper surface 110b) sides of the metallic plate may include the first pad (as one example, the pad 131), the second pad (as one example, the pad 132), and the wiring (as one example, the wiring 134). The first pad may be formed at a position corresponding to a position of the first through-hole provided in the bent portion. The second pad may be formed at a position corresponding to a position of the first through-hole provided in the flange portion. The wiring may connect the first pad and the second pad. As a result of this, in a region in which the bent portion and the flange portion are overlapped each other when viewed from the top, it is possible to implement the feeding of electricity and the signal transmission from the mounting substrate to the other electronic component.

Furthermore, the flange portion may be divided by way of the slits (as one example, the slits 112a). As a result of this, it is possible to improve the cooling efficiency of the electronic components in the space provided in the bent portion.

Furthermore, the wiring substrate according to the embodiment may further include another insulating layer (as one example, the insulating layer 170) that is provided on the wiring layer disposed on the other surface sides of the metallic plate, another wiring layer (as one example, the wiring layer 180) that is provided on the other insulating layer, and the via wiring (as one example, the via wiring 185) that is provided in the other insulating layer. The other wiring layer may be connected to the wiring layer by way of the via wiring. As a result of this, it is possible to improve the flexibility of the wiring layout of the wiring substrate.

Furthermore, the wiring substrate according to the embodiment may further include the electronic component (as one example, the IC chip 220) that is accommodated in the space and that is electrically connected to the wiring layer disposed on the one of the surface sides of the metallic plate. As a result of this, it is possible to improve the heat radiation efficiency from the electronic components to the wiring substrate.

According to an aspect of an embodiment of the wiring substrate disclosed in the present application, an advantage is provided in that it is possible to improve heat radiation efficiency.

(Note) A method of manufacturing a wiring substrate, the method comprising:
preparing a metallic plate;
forming a first through-hole in the metallic plate;
forming an insulating layer on both surfaces of the metallic plate such that a part of the insulating layer fills the first through-hole;
forming a second through-hole at a portion in which the insulating layer fills the first through-hole;
forming a wiring layer on the insulating layer on both surface sides of the metallic plate; and
forming feedthrough wiring that connects the wiring layer disposed on both surface sides of the metallic plate to the second through-hole, wherein
the preparing the metallic plate includes forming the metallic plate that includes a bent portion that is bent in a bottomed box shape and that forms a space capable of accommodating an electronic component on one of the surface sides of the metallic plate.

All examples and conditional language recited herein are intended for pedagogical purposes of aiding the reader in understanding the invention and the concepts contributed by the inventor to further the art, and are not to be construed as limitations to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A wiring substrate comprising:
a metallic plate;
a first through-hole that is formed in the metallic plate;
an insulating layer that covers both surfaces of the metallic plate and an inner wall surface of the first through-hole;
a second through-hole that is formed on an inner side of the insulating layer in the first through-hole;
a wiring layer that is laminated on the insulating layer on both surface sides of the metallic plate; and
feedthrough wiring that is formed in the second through-hole, and that connects the wiring layer disposed on both surface sides of the metallic plate, wherein
the metallic plate incudes a bent portion that is bent in a bottomed box shape and that forms a space on one of the surface sides of the metallic plate.

2. The wiring substrate according to claim 1, wherein the metallic plate includes a flange portion that is formed at an outer periphery of the bent portion, and that protrudes in a direction away from the space.

3. The wiring substrate according to claim 2, wherein
the first through-hole is formed in the bent portion and the flange portion, and
the wiring layer disposed on another of the surface sides of the metallic plate includes
a first pad that is formed at a position corresponding to a position of the first through-hole provided in the bent portion,
a second pad that is formed at a position corresponding to a position of the first through-hole provided in the flange portion, and
wiring that connects the first pad and the second pad.

4. The wiring substrate according to claim 2, wherein the flange portion is divided by way of a slit.

5. The wiring substrate according to claim 1, further comprising
another insulating layer that is provided on the wiring layer disposed on another of the surface sides of the metallic plate;
another wiring layer that is provided on the other insulating layer; and
via wiring that is provided in the other insulating layer, wherein
the other wiring layer is connected to the wiring layer by way of the via wiring.

6. The wiring substrate according to claim 1, further comprising an electronic component that is accommodated in the space, and that is electrically connected to the wiring layer disposed on the one of the surface sides of the metallic plate.

7. An electronic device comprising:
a first wiring substrate;
an electronic component that is fixed on the first wiring substrate;
a second wiring substrate that is mounted on the electronic component and the first wiring substrate; and
another electronic component that is mounted on the second wiring substrate, wherein
the second wiring substrate includes
a metallic plate,
a first through-hole that is formed in the metallic plate,
an insulating layer that covers both surfaces of the metallic plate and an inner wall surface of the first through-hole,
a second through-hole that is formed on an inner side of the insulating layer in the first through-hole,
a wiring layer that is laminated on the insulating layer on both surface sides of the metallic plate, and
feedthrough wiring that is formed in the second through-hole, and that connects the wiring layer disposed on both surface sides of the metallic plate,
the metallic plate includes a bent portion that is bent in a bottomed box shape and that forms a space capable of accommodating the electronic component on one of the surface sides of the metallic plate,
the electronic component is accommodated in the space, and is electrically connected to the wiring layer disposed on the one of the surface sides of the metallic plate, and
the other electronic component is electrically connected to the wiring layer disposed on another of the surface sides of the metallic plate.
